(19) United States
(12) Patent Application Publication
(10) Pub. No.: US 2021/0223423 A1
(43) Pub. Date: Jul. 22, 2021

(54) SYNTHETIC MODELING WITH NOISE SIMULATION

(71) Applicant: SHELL OIL COMPANY, HOUSTON, TX (US)

(72) Inventors: Donald Paul GRIFFITH, Houston, TX (US); Sam Ahmad ZAMANIAN, Houston, TX (US); Russell David POTTER, Houston, TX (US); Antoine Victor Applolinaire VIAL-AUSSAVY, Houston, TX (US)

(21) Appl. No.: 15/733,920

(22) PCT Filed: Apr. 16, 2019
(86) PCT No.: PCT/US2019/027708

§ 371 Date: Dec. 1, 2020

Related U.S. Application Data
(60) Provisional application No. 62/679,206, filed on Jun. 1, 2018.

(51) Int. Cl. G01V 1/28; G01V 1/30; G06N 3/08; G06F 30/27

(52) U.S. Cl. CPC G01V 1/282; G01V 1/302; G01V 2210/64; G06F 30/27; G01V 2210/66; G06N 3/084

(57) ABSTRACT

A method for producing a synthetic model for training a backpropagation-enabled process for identifying subsurface features, includes generating noise-free synthetic subsurface models with realizations of subsurface features. The noise-free synthetic subsurface models are generated by introducing a model variation selected from geologically realistic features simulating the outcome of a geologic process, simulations of geologic processes, and combinations thereof. Labels are applied to one or more of the subsurface features in one or more of the synthetic subsurface models. A simulation of a noise source is applied to a copy of one or more of the noise-free synthetic subsurface models to produce a noise-augmented copy. The labels and the corresponding synthetic subsurface models are imported into the backpropagation-enabled process for training.

### FIELD OF THE INVENTION

The present invention relates to backpropagation-enabled processes, and in particular to producing a synthetic model for training a backpropagation-enabled process for identifying subsurface features.

### BACKGROUND OF THE INVENTION

Subsurface models are used for hydrocarbon exploration or other geotechnical studies. Typically, subsurface models are developed by interpreting seismic and other remote-sensing data, and well logging data. The process for developing subsurface models from such field-acquired data is time- and data-intensive. Backpropagation-enabled machine learning processes offer the opportunity to speed up time-intensive interpretation processes. Many investigators are using field-acquired seismic data for training the backpropagation-enabled processes. In such cases, investigators apply labels to identified geologic features as a basis for training the backpropagation-enabled process.

WO2018/026995A1 (Schlumberger '995) relating to a method for “Multi-Scale Deep Network for Fault Detection” by generating patches from a known seismic volume acquired from field data, the known seismic volume having known faults. Labels are assigned to the patches and represent a subset of the training areas in a patch. The patch is a contiguous portion of a section of the known seismic volume and has multiple pixels (e.g., 64×64 pixels). The patch is intersected by a known fault specified by a user. A machine learning model is trained by the label for predicting a result to identify an unknown fault in a target seismic volume.

A disadvantage of using field-acquired data for machine learning is that human error or bias is often introduced into field-acquired seismic data interpretation. For example, a human interpreter may draw a series of straight lines to identify a fault, but the fault does not fall exactly on the straight-line segments. Conventional processes, such as those described above, are then trained on a flawed label. Furthermore, field-acquired data may either be difficult to obtain or be cumbersome to manage.

Accordingly, there have been some attempts to use synthetic models for training a backpropagation-enabled process. For example, Huang et al. (“A scalable deep learning platform for identifying geologic features from seismic attributes,” The Leading Edge 249-256; March 2017) describe identifying geologic faults by applying deep learning technology on a seismic data analytics platform. Huang et al.'s workflow includes calculating seismic attributes, extracting features, training a convolutional neural network (CNN) and predicting geologic faults by applying the CNN models. The fault detection model was trained using nine attributes computed from a synthetic volume derived from images constructed using a simple seismic volume generation program provided with public domain software for image processing for faults by Hale (Hale, D., 2014, Seismic image processing for geologic faults, https://github.com/dhale/ipf, accessed 10 Nov. 2016 per Huang et al.).

Fault detection models trained using synthetic data show promise for improving efficiency in training a backpropagation-enabled process. However, to date, efforts have been based on over-simplified realizations of a subsurface formation. In reality, for example, faults may themselves be more irregular and other geological features, beyond faults, exist in the formation. Furthermore, a backpropagation-enabled process, once trained, will typically be applied to field-acquired data, which has some degree of noise from seismic acquisition, from seismic processing, from an imaging process, and, often, from combinations thereof. There is a need for a model that simulates noise for training backpropagation-enabled processes.

### SUMMARY OF THE INVENTION

According to one aspect of the present invention, there is provided a method for producing a synthetic model for training a backpropagation-enabled process for identifying subsurface features, the method comprising the steps of: (a) generating a plurality of noise-free synthetic subsurface models, the plurality of noise-free synthetic subsurface models having realizations of subsurface features, wherein the plurality of noise-free synthetic subsurface models is generated by introducing a model variation selected from geologically realistic features simulating the outcome of a geologic process, simulations of geologic processes, and combinations thereof; (b) applying labels to one or more of the subsurface features in one or more of the plurality of synthetic subsurface models; (c) creating a copy of one or more of the plurality of noise-free synthetic subsurface models; and (d) applying a simulation of a noise source to the copy to produce a noise-augmented copy.

### BRIEF DESCRIPTION OF THE DRAWINGS

The method of the present invention will be better understood by referring to the following detailed description of preferred embodiments and the drawings referenced therein, in which:

FIG. 1 is a black and white rendering of PRIOR ART FIG. 7 of Huang et al., illustrating “a synthetic seismic volume with five faults used to train the fault-detection model”; and

FIG. 2 is a black and white rendering of an embodiment of a synthetic cube produced according to the present invention.

### DETAILED DESCRIPTION OF THE INVENTION

The present invention provides a method for producing a synthetic model for training a backpropagation-enabled process for identifying subsurface features. Once trained, the process can be applied to field-acquired seismic data with improved identification of a subsurface geologic feature.

By using data from the synthetic models to train a backpropagation-enabled process, the effectiveness and accuracy of the training is significantly improved. Examples of backpropagation-enabled processes include, without limitation, artificial intelligence, machine learning, and deep learning. It will be understood by those skilled in the art that advances in backpropagation-enabled processes continue rapidly. The method of the present invention is expected to be applicable to those advances even if under a different name. Accordingly, the method of the present invention is applicable to the further advances in backpropagation-enabled process, even if not expressly named herein.

The use of synthetic data, preferably pseudo-realistic data, for training a backpropagation-enabled process for seismic data has two principle benefits. First, the model and associated labels can be generated in accordance with the present invention in a significantly shorter period of time, with related cost savings. Conversely, the generation of labels from field-acquired data can take years and involves sorting through excess details of information. Also, the interpretation and labeling of field-acquired data has a degree of human error and/or bias involved. For example, in the interpretation of field-acquired data, faults are “picked” by drawing a series of straight lines. But the fault may not fall exactly along the straight-line segments. Accordingly, a degree of error is inadvertently introduced into the training model. Furthermore, noise introduced in seismic data acquisition, seismic processing and/or image processing may distort and/or hide subsurface features, thereby creating further error in the training model. In accordance with the present invention, the synthetic training model is substantially free of human error.

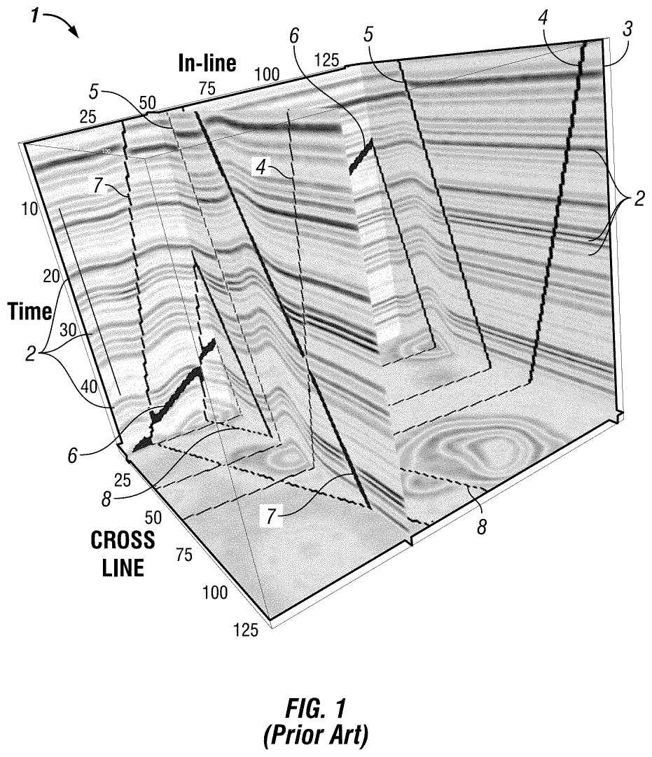

As discussed above, Huang et al. describe identifying geologic faults by training a fault detection model with a synthetic volume constructed using a simple seismic volume generation program. FIG. 1 is a black and white rendering of PRIOR ART FIG. 7 of Huang et al., illustrating “a synthetic seismic volume with five faults used to train the fault-detection model.” A synthetic seismic volume 1 has a plurality of subsurface layers 2. As shown in the back face 3 of the synthetic seismic volume 1, the subsurface layers 2 were originally depicted as being horizontal, parallel and some variation in uniform thickness relative to other subsurface layers 2. Huang et al. describe applying five faults 4, 5, 6, 7, 8 to the synthetic seismic volume 1. The seismic volume generation program used by Huang et al. caused some deviation from horizontal in the subsurface layers, for example between faults 5 and 6. However, the boundaries of the subsurface layers 2 remained parallel in the synthetic seismic volume 1. Also, the faults 4, 5, 6, 7, 8 were applied from one face to another face of the synthetic seismic volume 1 after the synthetic seismic volume 1 was generated, with no variation in geologic time. Furthermore, no other geologic features or processes, beyond simplified faults, are introduced to synthetic seismic volume 1. As such, Huang et al.'s synthetic model is an over-simplified realization of a subsurface formation. Huang et al. demonstrated training by applying the machine learning to another oversimplified synthetic model. Furthermore, Huang et al. do not introduce a simulation of noise that would be found in field-acquired data. Accordingly, results will not be as effective or accurate for training a backpropagation-enabled process to predict the complexity and subtlety of subsurface features in field-acquired data.

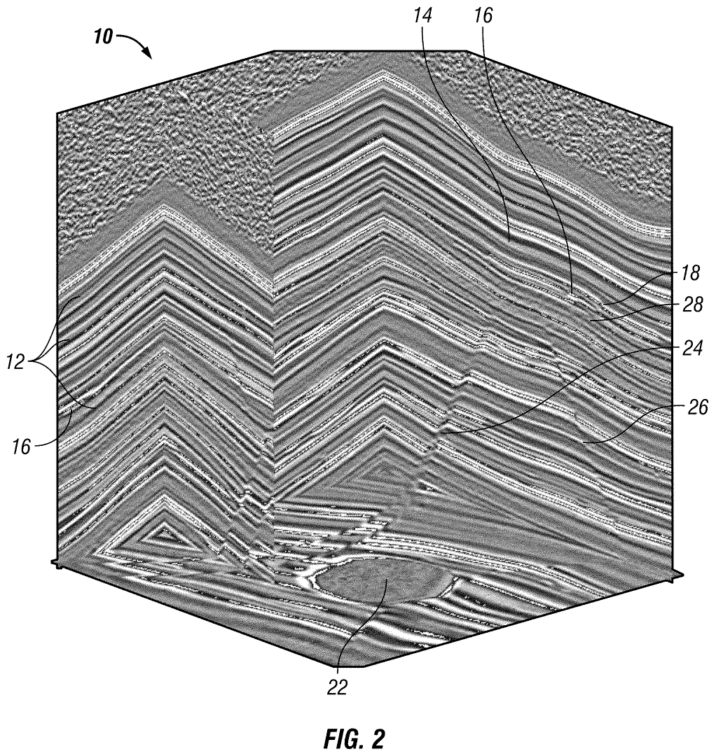

One embodiment of a synthetic cube 10 produced according to the method of the present invention is illustrated in FIG. 2. In accordance with the method of the present invention, synthetic subsurface models are generated to produce imaginary realizations of subsurface features. The models are generated by introducing variations in the subsurface features. The variations can be geologically realistic features simulating the outcome of a geologic process, simulations of geologic processes, simulations of noise sources, and combinations thereof. In accordance with the present invention, the plurality of synthetic subsurface models has at least three distinct model variations.

By “model variation”, we mean introducing a change in a 3D series of layers having substantially horizontal and parallel boundary layers.

The synthetic cube 10 has successive layers 12. The geologically realistic features simulating the outcome of a geologic process include, for example, without limitation, boundary layer variations, overlapping beds, rivers, channels, tributaries, salt domes, basins, and combinations thereof. It will be understood by those skilled in the art that other geologically realistic features could be introduced in the method of the present invention without departing from the scope of the present invention.

An example of a geologically realistic feature is a boundary layer variation, where at least one non-parallel boundary layer is introduced. In other words, the thickness of the layer is non-uniform. An example of this is illustrated in FIG. 2, in boundary layer 14. FIG. 2 also illustrates channels 16 and overlapping beds 18. A salt body 22 is also depicted.

Simulations of geologic processes include, for example, without limitation, mimicking tectonic deformation, erosion, infilling, and combinations thereof. Another example of a simulation of geologic processes includes introducing a geologically realistic feature while a model is being generated (i.e., before all layers are produced) to simulate geologic time. It will be understood by those skilled in the art that other simulations of geologic processes could be introduced in the method of the present invention without departing from the scope of the present invention.

Examples of tectonic deformation processes include, without limitation, earthquakes, creep, subsidence, uplift, erosion, tensile fractures, shear fractures, thrust faults, and combinations thereof. Mimicking tectonic deformation processes include, without limitation, tilting one or more layers in a 3D model, faulting one or more layers in a 3D model, and combinations thereof. A fault may be introduced to extend through some or all layers after all successive layers are produced on top of a 3D deepest layer. Alternatively, a fault may be introduced when only some of the layers are produced on top of the 3D deepest layer. In a further embodiment, the inventive method introduces multiple realizations of faults generated both during and after the successive layers are produced. The embodiment of the synthetic cube 10 illustrates a first fault 24 having a transition zone and a second fault 26 that has a sharp edge.

Simulations of an erosion process includes introducing characteristics of an erosion pattern, width and depth, for example, through one or more layers.

Simulations of noise sources include, for example, without limitation, mimicking the noise and seismic response resulting from a seismic acquisition, from seismic processing, from an imaging process, and from combinations thereof. A depiction of a seismic processing artifact is illustrated by the mottled region 28.

In one embodiment, the seismic response is simulated seismic data from multiple simulated source locations and/or multiple simulated receiver locations. In a preferred embodiment the seismic response includes multiple offsets and/or multiple azimuths for all common midpoints for the simulated seismic data. The common midpoints may be measured in a time domain or a depth domain.

Meta-data labels describing subsurface features are assigned to the seismic data according to the method of the present invention. The labels and corresponding synthetic subsurface models are imported into the backpropagation-enabled process for training.

By generating a plurality of synthetic subsurface models, many subsurface features can be labeled to train the backpropagation-enabled process with different images of the same subsurface features and/or images of different subsurface features. An advantage of the method of the present invention is the ability to generate a significant number of images for training. By producing images of a subsurface feature in different scenarios, the training accuracy of the backpropagation-enabled process is improved. For example, labels identifying a river that is wide and shallow in one realization, narrow and deep in another realization, and wide and deep in yet another realization will more effectively train a backpropagation-enabled process to learn what a river looks like in field-acquired data.

In a preferred embodiment, the synthetic subsurface models are generated by producing a 3D deepest layer, producing a plurality of successive 3D layers on top of the 3D deepest layer, and introducing model variations during and/or after producing the successive 3D layers. The model variations are used to create imaginary realizations of subsurface features. However, they are not necessarily intended to exactly replicate an existing subsurface region. An objective is to create a significant number of images and while the features themselves may be geologically realistic, the combination of model variations in one or more subsurface models need not necessarily be geologically realistic.

Preferably, the layers for the synthetic subsurface models are assigned geologically realistic rock properties. More preferably, the synthetic subsurface models are generated with a geologically realistic distribution of rock properties between neighboring layers.

Preferably, the model variations introduced to the subsurface models are consistent with the rock properties. Rock properties are depicted by the strength of reflectivity in layers.

In preferred embodiments, multiple realizations of the model variations are introduced to the subsurface models. For example, multiple realizations of the same model variation, for example a fault, are introduced. As another example, multiple realizations of noise source simulations are introduced. For example, after introducing a simulation of noise from a conventional electronic seismic recording instrument, another noise source simulation, such as seismic processing and/or image processing is introduced.

In the method of the present invention, a noise-free copy of the synthetic models is preserved and a noise-augmented copy of the synthetic models is created. Simulations of noise sources are applied to at least one of the synthetic subsurface models of the noise-augmented copy.

Preferably, the backpropagation-enabled process is trained with labels applied to a selected subsurface feature in the noise-free copy and a corresponding label of the selected subsurface feature in the noise-augmented copy.

Generally, labels applied in the noise-free copy of synthetic models remain unchanged in the noise-augmented copy of synthetic models. In some embodiments, labels may need to be modified in a noise-augmented synthetic model when noise simulations, for example stretching or squeezing augmentations, change the registration between the labels and corresponding data.

While preferred embodiments of the present invention have been described, it should be understood that various changes, adaptations and modifications can be made therein within the scope of the invention(s) as claimed below.

1. A method for producing a synthetic model for training a backpropagation-enabled process for identifying subsurface features, the method comprising the steps of:
(a) generating a plurality of noise-free synthetic subsurface models, the plurality of noise-free synthetic subsurface models having realizations of subsurface features, wherein the plurality of noise-free synthetic subsurface models is generated by introducing a model variation selected from geologically realistic features simulating the outcome of a geologic process, simulations of geologic processes, and combinations thereof;
(b) applying labels to one or more of the subsurface features in one or more of the plurality of synthetic subsurface models;
(c) creating a copy of one or more of the plurality of noise-free synthetic subsurface models; and
(d) applying a simulation of a noise source to the copy to produce a noise-augmented copy.

2. The method of claim 1, wherein step (a) comprises the steps of:
(a1) producing a 3D deepest layer,
(a2) producing a plurality of successive 3D layers on top of the 3D deepest layer, and
(a3) introducing at least one model variation.

3. The method of claim 1, further comprising the step of modifying the labels in the noise-augmented copy when registration between the labels and the synthetic subsurface model is changed by step (d).

4. The method of claim 1, wherein the simulation of a noise source is selected from mimicking a noise and seismic response resulting from a seismic acquisition, from seismic processing, from an imaging process, and from combinations thereof.

5. The method of claim 4, wherein at least two simulations of noise sources are introduced to one or more of the plurality of synthetic subsurface models.

6. The method of claim 5, wherein the at least two simulations of noise sources are the same or different.

7. The method of claim 2, wherein the model variation includes providing at least one non-parallel boundary layer to the plurality of successive 3D layers produced in step 2(a2).

8. The method of claim 2, wherein the simulations of geologic processes includes mimicking at least one tectonic deformation process by tilting one or more of the plurality of successive 3D layers already produced.

9. The method of claim 2, wherein the simulations of geologic processes includes mimicking at least one tectonic deformation process by faulting one or more of the plurality of successive 3D layers already produced.

10. The method of claim 2, wherein step (a) further comprises the step of assigning geologically realistic rock properties to one or more of the plurality of successive 3D layers.

11. The method of claim 2, wherein the simulations of geologic processes includes mimicking erosion within one or more of the plurality of successive 3D layers.

12. The method of claim 1, wherein the backpropagation-enabled process is selected from the group consisting of artificial intelligence, machine learning, deep learning and combinations thereof.

13. The method of claim 2, wherein step (a3) is repeated for another realization of the same model variation.

14. The method of claim 1, wherein labels of a predetermined subsurface feature in the noise-free copy and the predetermined subsurface feature in the noise-augmented copy are imported into the backpropagation-enabled process for training.

15. The method of claim 4, wherein the seismic response is simulated seismic data from multiple simulated source locations, multiple simulated receiver locations, and combinations thereof.

16. The method of claim 15, wherein the seismic response comprises multiple offsets, multiple azimuths, and combinations thereof for all common midpoints for the simulated seismic data.

17. The method of claim 16, wherein the common midpoints are measured in a time domain.

18. The method of claim 16, wherein the common midpoints are measured in a depth domain.
